(19) United States
(12) Patent Application Publication
(10) Pub. No.: US 2022/0341669 A1
(43) Pub. Date: Oct. 27, 2022

(54) HEAT-RADIATION APPARATUS AND MANUFACTURING METHOD THEREOF

(71) Applicant: NEC Corporation, Tokyo (JP)

(72) Inventors: Mahiro HACHIYA, Tokyo (JP); Minoru YOSHIKAWA, Tokyo (JP); Masaki CHIBA, Tokyo (JP)

(73) Assignee: NEC Corporation, Tokyo (JP)

(21) Appl. No.: 17/725,801

(22) Filed: Apr. 21, 2022

(30) Foreign Application Priority Data
Apr. 23, 2021 (JP) 2021-073033

(51) Int. Cl. F28D 1/04

(52) U.S. Cl. CPC F28D 1/0443; F28F 2280/06; F28F 2250/08

(57) ABSTRACT

A heat-radiation apparatus includes a housing and a plurality of heat-radiation modules which are aligned in a vertically-slanted manner with a predetermined inclination angle to a vertical line in the housing. A plurality of heat-radiation modules includes a plurality of heat exchangers which is aligned together in parallel and equipped with a plurality of fans to parallelize axial lines thereof with each other. In a manufacturing method of the heat-radiation apparatus, the number of heat-radiation modules is adjusted according to a radiation amount which is determined in advance.

### CROSS-REFERENCE TO RELATED APPLICATION

The present application claims the priority benefit of Japanese patent Application No. 2021-73033 filed on Apr. 23, 2021, the subject matter of which is hereby incorporated herein by reference.

### BACKGROUND OF THE INVENTION

### 1. Field of the Invention

The present invention generally relates to a heat-radiation apparatus and a manufacturing method of a heat-radiation apparatus.

### 2. Description of Related Art

In general, air conditioners (e.g., package air conditioners using refrigerating cycles) are used to cool server rooms at data centers. Heat radiators are adapted to exterior units of air conditioners using refrigerating cycles installed in data centers. Exterior units of air conditioners utilizing large-size fans each having a diameter of 600 mm or so are driven by an AC power supply such that the large-size fans can supply outside air to one to several heat exchangers. It is known that fans are used to supply outside air toward heat exchangers adapted to air conditioners, which are disclosed in various documents such as Patent Document 1 through Patent Document 6.

Patent Document 1: Japanese Patent Application Publication No. 2014-163530

Patent Document 2: Japanese Patent Application Publication No. S61-128074

Patent Document 3: Japanese Utility-Model Application Publication No. H01-120018

Patent Document 4: Japanese Patent Application Publication No. 2008-209043

Patent Document 5: Japanese Patent Application Publication No. 2004-218969

Patent Document 6: Japanese Patent Application Publication No. 2004-263923

In the above, Patent Document 1 discloses an air conditioner (having compression refrigerating cycles and coolant-pumping cycles) equipped with a compressor and a heat exchanger such that air introduced into an exterior unit may pass through the heat exchanger, from which an exterior blower may blow air to the outside. Patent Document 2 discloses an exterior unit of an air-cooled freezer equipped with a pair of heat exchangers having sheets combined together in a V-shaped manner. Patent Document 3 discloses a windbreaking structure of a refrigerator equipped with heat-exchanger units each including a pair of heat exchangers aligned in a V-shape manner and a blower. Patent Document 4 discloses a wind-direction control device adapted to electronic devices and configured of a wind-guide structure having seven wind-guide blades and a fan unit including fans. Patent Document 5 discloses a small-size heat exchanger, adaptable to information communication devices, having microtubes configured to flow coolants therethrough. Patent Document 6 discloses an air-conditioner exterior unit including heat-exchanger units and propeller fans vertically aligned together.

The aforementioned air-conditioning technologies using heat exchangers and fans may suffer from problems as follows.
(a) Large-size fans especially applied to exterior units of air conditioners are generally driven by an AC power supply. This does not comply with recent requirements to use DC power supply for air conditioners so as to save power consumption of data centers.
(b) Since large-size fans are driven by an AC power supply, it is difficult to achieve hot-swapping to substitute a spare machine for a main machine during its operating condition.
(c) Considering cooling performance, redundancy, preparation of a spare machine in case of failures, it is necessary to adopt excessive cooling capacity and a large number of heat exchangers coupled with fans beyond performance requirements.

Patent Document 1 employs a single fan for a single heat exchanger while Patent Document 2 employs a pair of heat exchangers having sheets combined together in a V-shaped manner. Patent Document 3 employs a single fan for a pair of heat exchangers, wherein a high windbreaking plate is interposed between adjacent pairs of heat exchangers while a low windbreaking plate is interposed between the paired heat exchangers. Patent Document 4 employs a wind-guide structure having seven wind-guide blades which can be manually operated to adjust the direction of wind caused by rotating fans of a fan unit. Patent Document 5 employs two types of fans (e.g., an axial-flow fan and a centrifugal fan) to increase an area of heat-radiating surfaces of microtubes, thus improving the cooling effect. Herein, substantially no space allowing for partition is provided between a heat exchanger and a fan. Patent Document 6 teaches a rectangular-shaped base for vertically arranging heat-exchanger units and propeller fans without any partition therebetween. None of Patent Document 1 through Patent Document 6 can solve the aforementioned problems in air-conditioning exterior units for server rooms.

The present invention is made in consideration of the aforementioned problems and aims to provide a heat-radiation apparatus and a manufacturing method of a heat-radiation apparatus preferably adapted to an exterior unit of an air conditioner using refrigerating cycles based on DC power.

### SUMMARY OF THE INVENTION

A first aspect of the present invention is directed to a heat-radiation apparatus including a housing and a plurality of heat-radiation modules, which are aligned in a vertically-slanted manner with a predetermined inclination angle to a vertical line in the housing. A plurality of heat-radiation modules includes a plurality of heat exchangers which is aligned together in parallel and equipped with a plurality of fans to parallelize axial lines thereof with each other.

A second aspect of the present invention is directed to a manufacturing method of a heat-radiation apparatus including a plurality of heat-radiation modules. The manufacturing method includes the steps of: aligning a plurality of heat-radiation modules including a plurality of heat exchangers in a vertically-slanted manner with a predetermined inclination angle to a vertical line in a housing such that a plurality of heat exchangers is aligned together in parallel and equipped with a plurality of fans to parallelize axial lines thereof with each other; and adjusting the number of heat-radiation modules as a plurality of heat-radiation modules according to a radiation amount which is determined in advance.

Accordingly, the present invention achieves an advantageous effect to produce a heat-radiation apparatus preferably adapted to an exterior unit of an air conditioner using refrigerating cycles based on DC power, thus facilitating the adjustment of cooling performance for servers in a data center.

### BRIEF DESCRIPTION OF THE DRAWINGS

FIG. 1 is a schematic illustration partly in section showing a heat-radiation apparatus with its minimum structure according to the non-limiting exemplary embodiment of the present invention. FIG. 2 is a flowchart showing a manufacturing method of the heat-radiation apparatus with its minimum structure.

FIG. 3 is a schematic diagram showing a cooling system utilizing the heat-radiation apparatus according to the first exemplary embodiment of the present invention.

FIG. 4 is a schematic illustration partly in section showing the internal structure of an exterior unit coupled with an interior unit in the cooling system of FIG. 4.

FIG. 5 is a perspective view partly in section showing a fixing structure of heat-radiation modules included in the heat-radiation apparatus.

FIG. 6 is a piping diagram showing a layout of pipes laid among heat-radiation modules.

FIG. 7A is a graph showing distributions of average windspeed associated with height positions in an elevation of heat-radiation modules combined together in a vertically-slanted alignment.

FIG. 7B shows a vertically-slanted alignment of heat exchangers individually equipped with their fans to blow air thereto.

FIG. 7C shows a vertically-slanted alignment of heat exchangers collectively equipped with a single fan to blow air thereto.

FIG. 8A shows a pair of heat-radiation modules positioned oppositely via a partition board such that their fans cause airflows in opposite directions.

FIG. 8B is a graph showing distributions of wind power caused by fans of heat-radiation modules associated with pressure losses of air pressure caused by fans of heat-radiation modules.

FIG. 9A shows two sets of three heat-radiation modules including one redundant heat-radiation module, which are each combined together in a vertically-slanted alignment and positioned opposite to each other via a partition board in a housing.

FIG. 9B shows two sets of thee heat-radiation modules including one redundant heat-radiation module in which another heat-radiation module fails in operation in the housing.

FIG. 10A shows two sets of three heat-radiation modules including one redundant heat-radiation module which may induce a short-return channel of outside air therearound due to an operating fan of an adjacent heat-radiation module.

FIG. 10B shows two sets of three heat-radiation modules equipped with shutters to permit or block circulations of outside air therearound.

FIG. 11 is a plan view of a fixing structure of a shutter attached to a front face of a fan for each heat-radiation module according to the second exemplary embodiment of the present invention.

FIG. 12A is a side view partly in section showing a closed state of the shutter whose sheet stays on the front face of a fan for each heat-radiation module.

FIG. 12B is side view partly in section showing an open state of the shutter whose sheet moves upwardly above the front face of a fan for each heat-radiation module.

FIG. 13A shows two sets of three heat-radiation modules which are aligned straightly in a vertically-slanted manner and positioned opposite to each other via a partition board in a housing.

FIG. 13B shows two sets of three heat-radiation modules aligned opposite to each other according to the third exemplary embodiment of the present invention, wherein a left-side set of three heat-radiation modules is aligned downwardly along a negative slope while a right-side set of three heat-radiation modules is aligned upwardly along a positive slope.

### DETAILED DESCRIPTION OF NON-LIMITING EXEMPLARY EMBODIMENTS

The present invention will be described in detail by way of non-limiting exemplary embodiments with reference to the accompanying drawings, wherein the same parts in the drawings will be denoted by the same reference numerals; hence, descriptions thereof will be omitted as necessary.

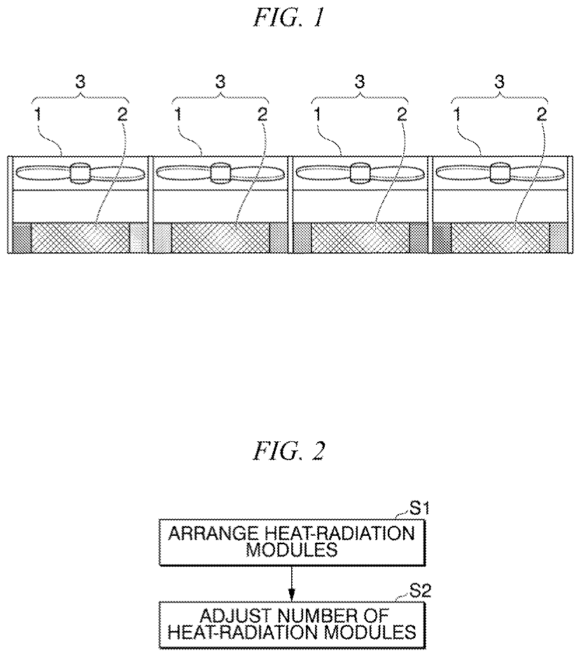

FIG. 1 is a schematic illustration partly in section showing a heat-radiation apparatus with its minimum structure according to a non-limiting exemplary embodiment of the present invention. The heat-radiation apparatus includes a plurality of heat-radiation modules 3 having fans 1 and heat exchangers 2, which are aligned in an axial direction of the fans 1 with a predetermined interval of distance therebetween. The heat exchangers 2 are juxtaposed with each other such that axial lines of the fans 1 thereof will be aligned in parallel with each other.

Since the heat-radiation apparatus includes a plurality of heat-radiation modules 3 having fans 1 and heat exchangers 2, it is possible to individually adjust a radiation amount of each heat-radiation module 3 or to individually operate or stop each heat-radiation module 3, thus making it easy for the heat-radiation apparatus to adjust its total radiation amount. In addition, it is possible to appropriately set a radiation amount of the heat-radiation apparatus according to its required cooling capacity by increasing or decreasing the number of heat-radiation modules 3.

Next, a manufacturing method of the heat-radiation apparatus with its minimum structure will be described below. FIG. 2 is a flowchart showing a manufacturing method of the heat-radiation apparatus with its minimum structure (steps S1, S2). In step S1, a manufacturer (e.g., a workman or an operator) should align a plurality of heat-radiation modules 3 having the fans 1 and the heat exchangers 2 in an axial direction of the fans 1 such that the heat-radiation modules 3 will be juxtaposed with each other with a predetermined interval of distance therebetween. In step S2, a manufacturer should adjust the number of heat-radiation modules 3 according to a radiation amount of a heat-radiation apparatus. According to the structure of the heat-radiation apparatus as shown in FIG. 1, it is possible to appropriately set a radiation amount of the heat-radiation apparatus according to its required cooling capacity by adjusting the number of heat-radiation modules 3.

### First Exemplary Embodiment

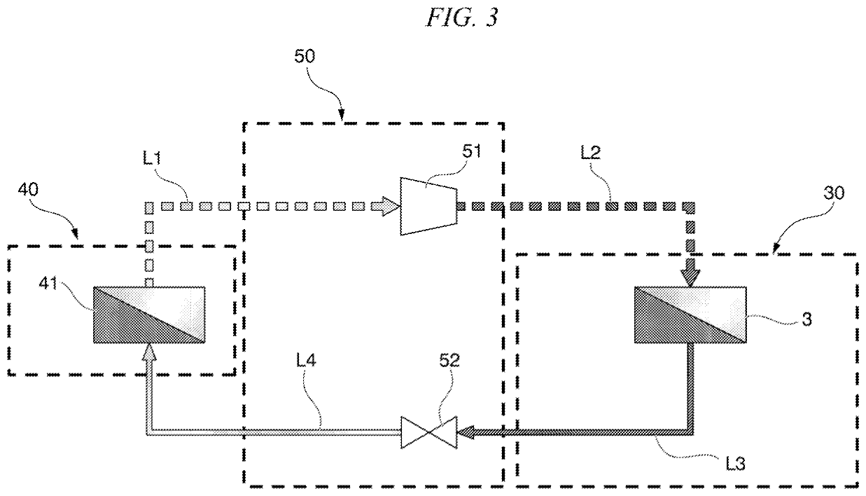

Next, the first exemplary embodiment of the present invention will be described in detail with reference to FIGS. 3-6, FIGS. 7A-7C, FIGS. 8A-8B, and FIGS. 9A-9B. FIG. 3 is a schematic diagram of a cooling system using a heat-radiation apparatus according to the first exemplary embodiment of the present invention. The cooling system is basically designed as an air-conditioning system, which includes an exterior unit 30 including the heat-radiation module 3, a heat-receiving unit 40 configured to receive heat from an exhaust emission of server units subjected to cooling, and an interior unit 50 configured to compress coolant which receives heat in the heat-receiving unit 30.

The heat-receiving unit 40 includes a heat exchanger (or an evaporator) 41 configured to receive heat from high-temperature air exhausted from servers (subjected to cooling) disposed in a server room (not shown). Specifically, the heat exchanger 41 is configured to receive heat from high-temperature exhaust air (whose temperature is higher than room temperature of a server room) which is absorbed by servers as cooling air. That is, an exhaust air exhausted into the server room is cooled by coolant flowing through the heat exchanger 41, thereafter, the cooled air is discharged into the server room and then taken in by servers as cooling air. The coolant having received heat via the heat exchanger 41 of the heat-receiving unit 40 is forced to flow into an interior unit 50. The interior unit 50 includes a compressor 51 configured to compress the coolant by a predetermined compression ratio.

The compressed coolant compressed by the compressor 51 is supplied to the exterior unit 30. The exterior unit 30 includes the heat exchanger 2 of the heat-radiation module 3 configured to condense the compressed coolant (whose temperature is increased due to compression) via heat exchange with outside air. In FIG. 3, reference symbols L1, L2 show channels having gaseous-phase coolant flowing therethrough, that is, the cooled coolant flows through the channel L1 from the heat-receiving unit 40 to the interior unit 50 while the compressed coolant flows through the channel L2 from the interior unit 50 to the exterior unit 30.

In FIG. 3, reference symbols L3, L4 show channels having liquid-phase coolant flowing therethrough. That is, the condensed coolant flows through the channel L3 from the exterior unit 30 to the interior unit 50. The condensed coolant is sent to an expansion valve 52 in the interior unit 50 and decompressed to a predetermined pressure due to expansion. The decompressed coolant flows through the channel L4 from the interior unit 50 to the heat-receiving unit 40. The decompressed coolant circulates in the heat-receiving unit 40 and is supplied to the heat exchanger 41 to cool exhaust air of servers.

When the outlet of the heat exchanger 41 of the heat-receiving unit 40 is positioned at a higher elevation than the expansion valve 52 of the interior unit 50, the liquid-phase coolant may flow into the expansion valve 52 due to a difference of elevation. However, due to some restrictions in piping arrangement, it is difficult to provide a sufficient difference of elevation between the interior unit 50 and the exterior unit 30. Alternatively, the interior unit 50 may be positioned at a higher elevation than the exterior unit 30. In this case, it is necessary to arrange a pump in the middle of the channel L3 directed from the exterior unit 30 to the interior unit 50, and therefore the pump is used to forcibly deliver the condensed coolant from the heat-radiation module 3 to the expansion valve 52.

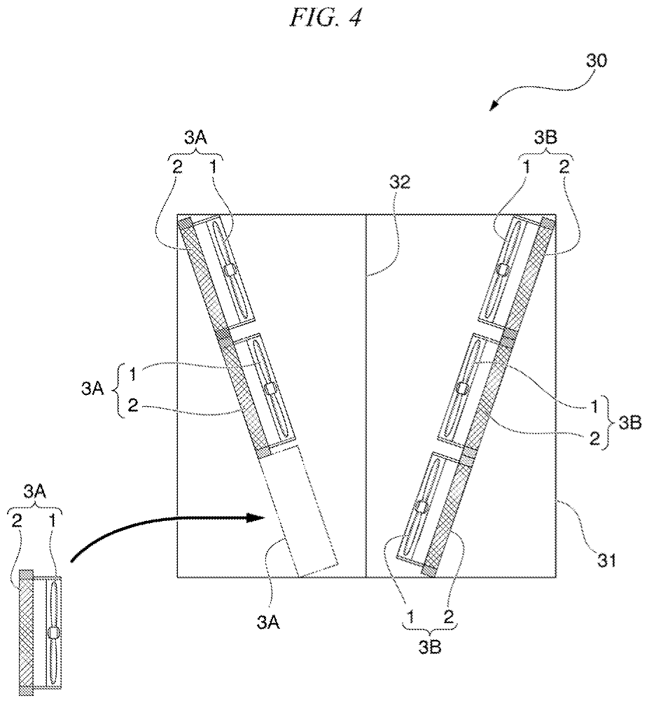

FIG. 4 shows the internal structure of the exterior unit 30, which includes a plurality of heat-radiation modules 3A, 3B (including the fans 1 and the heat exchangers 2) aligned in an inclined manner and enclosed in a housing 31. The housing 31 including an air inlet in its lower face and an air outlet in its upper face is arranged in the periphery of the exterior unit 30 or the outside of the exterior unit 30. As shown in FIG. 4, for example, the housing 31 is positioned in a longitudinal manner providing an air duct having air flowing from the lower face to the upper face thereof. A partition board (simply, referred to as a partition) 32 is arranged inside the housing 31 to partition the internal space into two sections in right-left directions (serving as separate air channels). In the left-side section (leftward from the partition board 32 in FIG. 4), three heat-radiation modules 3A are aligned in a slanted manner such that the axial directions of the fans 1 thereof are disposed in parallel with each other. In FIG. 4, it is possible for an operator to individually assemble or remove three heat-radiation modules 3A according to needs. In the right-side section (rightward from the partition board 32 in FIG. 4), three heat-radiation modules 3B are aligned in a slanted manner such that the axial directions of the fans 1 thereof are disposed in parallel with each other.

The heat-radiation modules 3A aligned in the left-side section are inclined leftward to a vertical airflow direction of the housing 31 while the heat-radiation modules 3B in the right-side section are inclined rightward to a vertical airflow direction of the housing 31. That is, the heat-radiation modules 3A and the heat-radiation modules 3B are inclined oppositely and disposed in line symmetry about the partition board 32. In this connection, the fans 1 included in the heat-radiation modules 3A, 3B are driven by DC motors operable via a DC power supply used in a server room such that DC motors can be individually driven or stopped as necessary.

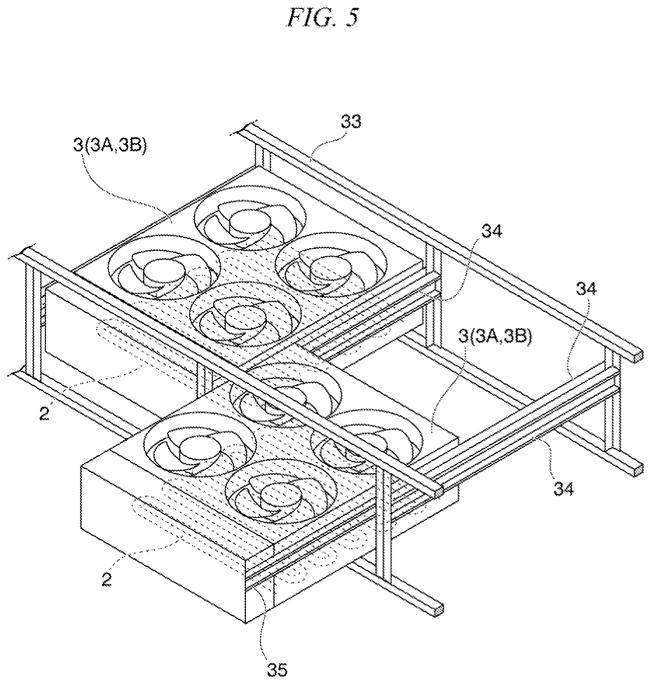

As shown in FIG. 5, the heat-radiation modules 3A, 3B are attached to and supported by a frame body 33. For example, the present exemplary embodiment copes with a failure of a single heat-radiation module 3A by attaching the heat-radiation module 3A to a position shown by dotted lines or removing the heat-radiation module 3A from the position shown by dotted lines. In this connection, FIG. 4 shows that each heat-radiation module 3 (among the heat-radiation modules 3A, 3B) includes a single fan 1 associated with a single heat exchanger 2. Alternatively, it is possible to employ a single fan used to supply outside air to a plurality of heat-radiation modules 3, or it is possible to employ a plurality of fans used to supply outside air to a single heat-radiation module 3.

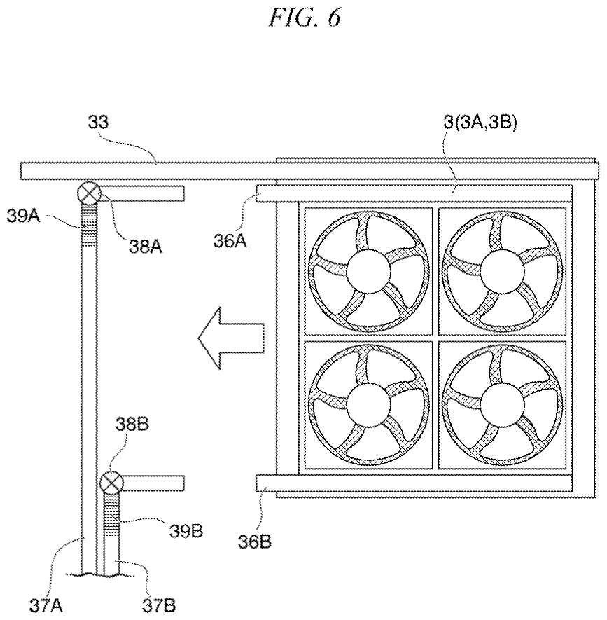

Next, a fixing structure of the heat-radiation modules 3 (3A, 3B) will be described with reference to FIGS. 5, 6. FIG. 5 shows that a single heat-radiation module 3 is equipped with four small-diameter fans; however, it is possible to arrange a single large-diameter fan for a single heat-radiation module 3. A single heat-radiation module 3 can be inserted into a single section (among plural sections) of the frame body 33, which includes a pair of support rails 34 to engage with a pair of move rails 35 attached to the opposite sides of the heat-radiation module 3 in its lateral direction. The heat-radiation module 3 may move into or retract from its corresponding section of the frame body 33 such that the paired move rails 35 of the heat-radiation module 3 may slide along the paired support rails 34 of the frame body 33. Thus, it is possible for an operator to arbitrarily draw in or out the heat-radiation module 3 in its corresponding section of the frame body 33.

FIG. 6 is a piping diagram showing a layout of pipes laid among heat-radiation modules 3. The heat exchanger 2 of the heat-radiation module 3 includes pipes, one of which serves as an incurrent pipe 36A having a high-pressure gaseous-phase coolant flowing therein and the other of which serves as an excurrent pipe 36B having a high-pressure liquid-phase coolant (after heat radiation) flowing therein. The incurrent pipe 36A receives the compressed gaseous-phase coolant (supplied from the compressor 51) via a steam branch pipe 37A while the excurrent pipe 36B outputs the heat-radiated liquid-phase coolant to a liquid branch pipe 37B.

Considering the operability of connecting or separating pipes due to the attachment/removal of the heat-radiation module 3, the present exemplary embodiment utilizes charge valves 38A, 38B capable of closing connections between the incurrent/excurrent pipes 36A/36B and the branch pipes 37A/37B. That is, the charge valve 38A is used to connect the incurrent pipe 36A and the stream branch pipe 37A while the charge valve 38B is used to connect the excurrent pipe 36B and the liquid branch pipe 37B.

Considering the operability of connecting or separating pipes due to the attachment/removal of the heat-radiation module 3, the present exemplary embodiment utilizes flexible pipes 39A, 39B in connection with the charge valves 38A, 38B. That is, the flexible pipe 39A is used to connect the steam branch pipe 37A and the charge valve 38A while the flexible pipe 39B is used to connect the liquid branch pipe 37B and the charge valve 38B. Similar to the aforementioned piping, a detachable connector (not shown) is arranged in a DC power supply pathway for a DC motor configured to drive the fan 1 in consideration of the attachment/removal of the heat-radiation module 3.

The heat-radiation apparatus having the aforementioned structure (adapted to the exterior unit 30 of the cooling system of FIG. 3) is able to minimize ununiform variations of radiation amounts among heat-radiation modules 3A, 3B since their fans 1 are configured to supply outside air to the heat exchangers 2.

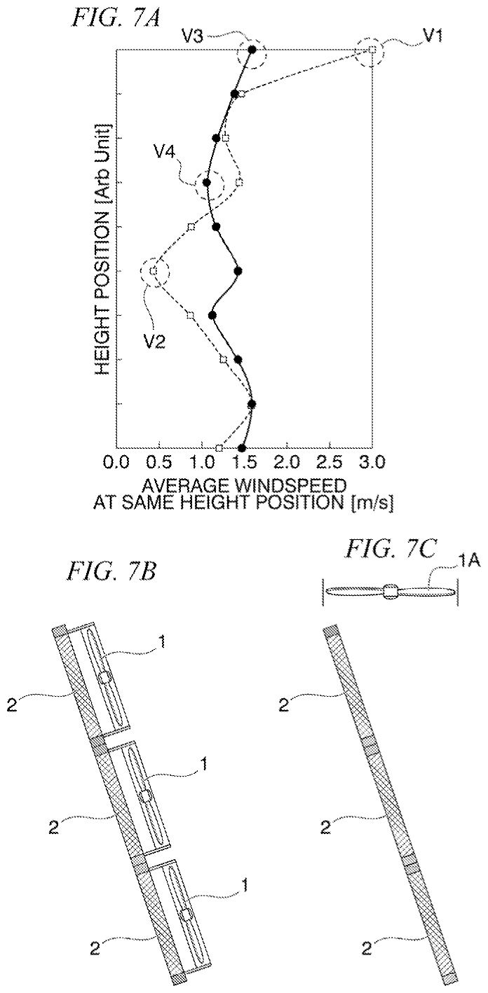

FIG. 7A is a graph showing examples of windspeed distributions in a height direction with respect to a first case (see FIG. 7B) in which a plurality of heat exchangers 2 combined together in a vertically-slanted alignment are individually equipped with their fans 1 and a second case (see FIG. 7C) in which a plurality of heat exchangers 2 combined together in a vertically-slanted alignment are collectively equipped with a single fan 1A. Herein, the height direction is an elevation of three heat exchangers 2 aligned together from their bottom to their top. In the second case of FIG. 7C, the “top-end” heat exchanger 2 at the highest elevation in a vertically-slanted alignment of three heat exchangers 2 is positioned close to the fan 1A while the “tail-end” heat exchanger 2 at the lowest elevation is positioned farther than the fan 1A.

A dotted polyline of FIG. 7A shows variations of windspeed in a height direction with respect to the second case of FIG. 7C in which a single fan 1A may blow air toward a vertically-slanted alignment of the heat exchangers 2 collectively, wherein a highest windspeed V1 appears at the top elevation in a vertically-slanted alignment of the heat exchangers 2 while a lowest windspeed V2 appears at the lower elevation in a vertically-slanted alignment of the heat exchangers 2. A solid polyline of FIG. 7A shows variations of windspeed in a height direction with respect to the first case of FIG. 7B in which the heat exchangers 2 combined together in a vertically-slanted alignment are individually equipped with their fans 1 which are rotated at the same rotation speed, wherein a relatively-high windspeed V3 appears at the highest elevation in a vertically-slanted alignment of the heat exchangers 2 while a relatively-low windspeed V4 appears at the lower elevation in a vertically-slanted alignment of the heat exchangers 2. As shown by the solid polyline of FIG. 7A, it is possible to reduce differences of windspeed irrespective of the elevation of the heat exchangers 2 in a vertically-slanted alignment direction since a difference between the windspeed V3 and the windspeed V4 is smaller than a difference between the windspeed V1 and the windspeed V2. In this connection, it is an effective measure to make uniform differences of windspeed in the height direction by individually controlling the rotation speed for each fan 1 among the fans 1 attached to the heat exchangers 2. In addition, it is an effective measure to individually control the rotation speed for each fan 1 according to magnitudes of radiation amounts due to ununiform variations of coolants to be branched from or supplied to the heat exchangers 2.

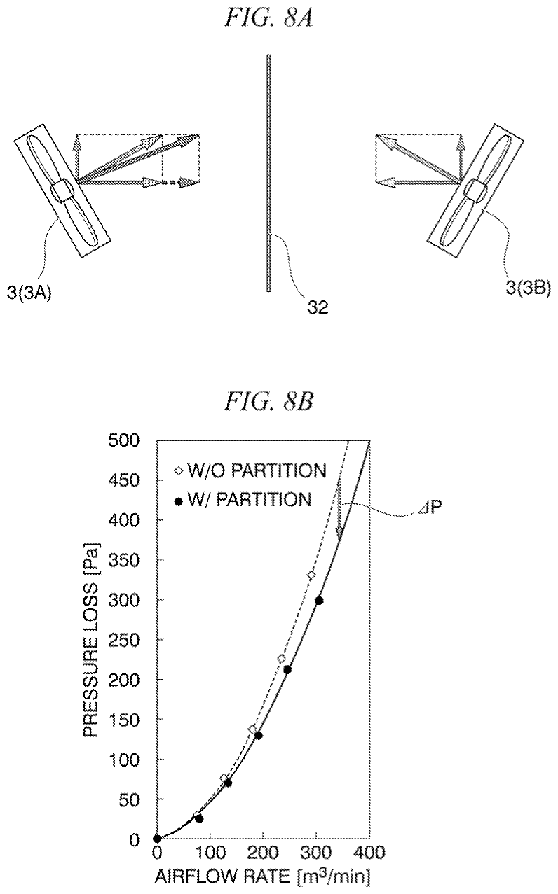

FIG. 8A shows a pair of heat-radiation modules 3A, 3B which are oppositely inclined and separated from each other with respect to the partition board 32, wherein the fan of the heat-radiation module 3A (hereinafter, referred to as a left-side fan) blows air toward the partition board 32 while the fan of the heat-radiation module 3B (hereinafter, referred to as a right-side fan) blows air toward the partition board 32 such that an airflow caused by the left-side fan in its axial direction is directed in an upper right direction while an airflow caused by the right-side fan in its axial direction is directed in an upper left direction. Specifically, the left-side fan of the heat-radiation module 3A causes wind pressure in its axial direction, which can be subjected to vector resolutions, i.e., a horizontal component and a vertical component. Similarly, the right-side fan of the heat-radiation module 3B causes wind pressure in its axial direction, which can be subjected to vector resolutions, i.e., a horizonal component and a vertical component. Since the heat-radiation module 3A and the heat-radiation module 3B are oriented oppositely about an intermediate position therebetween, the horizontal component of wind pressure caused by the left-side fan may mutually interfere with the horizontal component of wind pressure caused by the right-side fan, thus causing a pressure loss between the left-side fan and the right-side fan. The pressure loss may be increased to be higher as a distance between the heat-radiation modules 3A and 3B becomes smaller. For this reason, the partition board 32 is interposed between the left-side fan of the heat-radiation module 3A and the right-side fan of the heat-radiation module 3B, thus reducing the pressure loss due to an influence of the horizontal component of wind pressure of the left-side fan and the horizontal component of wind pressure of the right-side fan which mutually interfere with each other.

FIG. 8B is a graph showing variations of pressure losses occurring between the heat-radiation modules 3A, 3B with/without the partition board 32, specifically, variations of pressure losses in association with airflow rates. Specifically, a solid polyline of FIG. 8B shows variations of pressure losses with a partition in association with airflow rates while a dotted polyline of FIG. 8B shows variations of pressure losses without partition in association with airflow rates. Due to the nonexistence of the partition board 32 as shown by the dotted polyline of FIG. 8B, pressure losses will be increased as wind power of the left-side/right-side fans is increased to be higher. Due to the existence of the partition board 32 as shown by the solid polyline of FIG. 8B, it is possible to suppress an increase of pressure losses even though wind power of the left-side/right-side fans is increased to be higher. At an airflow rate of 300 m³/min, for example, it is possible to obtain a pressure-loss-suppressing effect of about ΔP=80 (Pa).

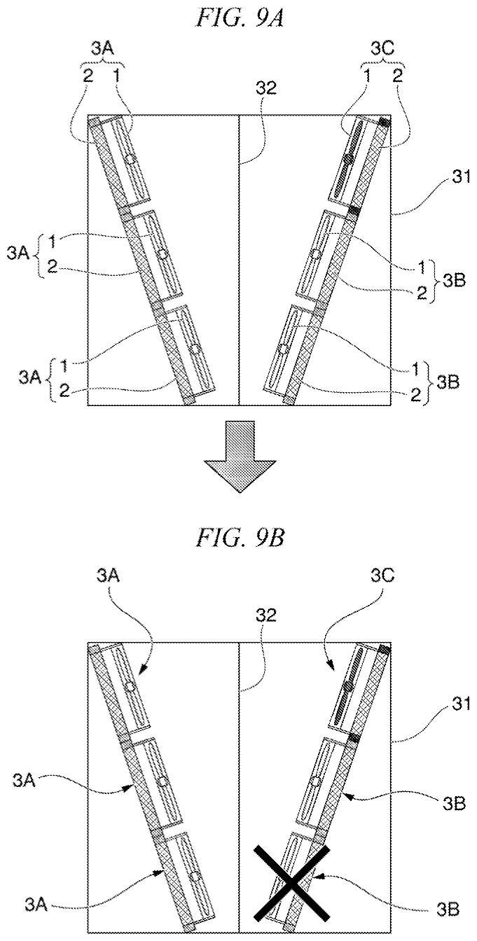

FIG. 9A shows two sets of heat-radiation modules 3 which are each combined together in a vertically-slanted alignment and positioned opposite to each other via the partition board 32 in the housing 31. Specifically, a left-side vertically-slanted alignment includes three heat-radiation modules 3A (each including the fan 1 and the heat exchanger 2) while a right-side vertically-slanted alignment includes two heat-radiation modules 3B (each including the fan 1 and the heat exchanger 2) and one redundant heat-radiation module 3C (including the fan 1 and the heat exchanger 2). In total, the housing 31 includes six heat-radiation modules 3 (3A, 3B, 3C) among which one heat-radiation module serves as the redundant heat-radiation module 3C, which may stop a coolant supply or an operation of its fan 1, alternatively, which may use a damper or a shutter (not shown) to cut out a flow of outside air; hence, the redundant heat-radiation module 3C is lodged in a suspension mode. Accordingly, heat will be dissipated by three heat-radiation modules 3A and two heat-radiation modules 3B.

FIG. 9B shows a failure event occurring in two sets of heat-radiation modules 3 shown in FIG. 9A. Specifically, FIG. 9B indicates a failure of the lower-right heat-radiation module 3B which stops operating the fan 1 thereof. After closing the pipes of the heat exchanger 2, the “redundant” upper-right heat-radiation module 3C starts operating the fan 1 thereof while starting supply of coolant by opening the valves of the incurrent pipe 36A and the excurrent pipe 36B associated with the heat exchanger 2. That is, the present exemplary embodiment is designed to start operating the redundant heat-radiation module 3C instead of the “failed” lower-right heat-radiation module 3B, thus maintaining a sufficient radiation amount over the entirety of the heat-radiation apparatus.

As to the failed heat-radiation module 3B which stops operating the fan 1, it is necessary to take off the steam branch pipe 37A and the liquid branch pipe 37B from the incurrent pipe 36A and the excurrent pipe 36B associated with the heat exchanger 2. Thereafter, the failed heat-radiation module 3B is removed from the frame body 33 and repaired to restore the functionality as necessary, and therefore the failed heat-radiation module 3B can be restored and treated as a new redundant heat-radiation module 3B in a suspension mode, which is returned to its original position in the frame body 33; hence, the redundant heat-radiation module 3B may prepare for a next failure event. Before returning the redundant heat-radiation module 3B to its original position in the frame body 33, it is necessary to vacuum and close pipes of the heat exchanger 2 using valves, thus securing smooth flowing of coolant when re-connecting the steam branch pipe 37A and the liquid branch pipe 37B to the incurrent pipe 36A and the excurrent pipe 36B.

The first exemplary embodiment is configured to cope with a failure occurring in any one of the heat-radiation modules 3 without stopping other heat-radiation modules by way of hot swapping in which a redundant heat-radiation module (e.g., the heat-radiation module 3C) is activated to start its operation while the failed heat-radiation module (e.g., the heat-radiation module 3B) is removed from an exterior unit and repaired as necessary. That is, the first exemplary embodiment demonstrates hot swapping to achieve maintenance work without affecting the operation of servers (subjected to cooling) installed in a server room.

### Second Exemplary Embodiment

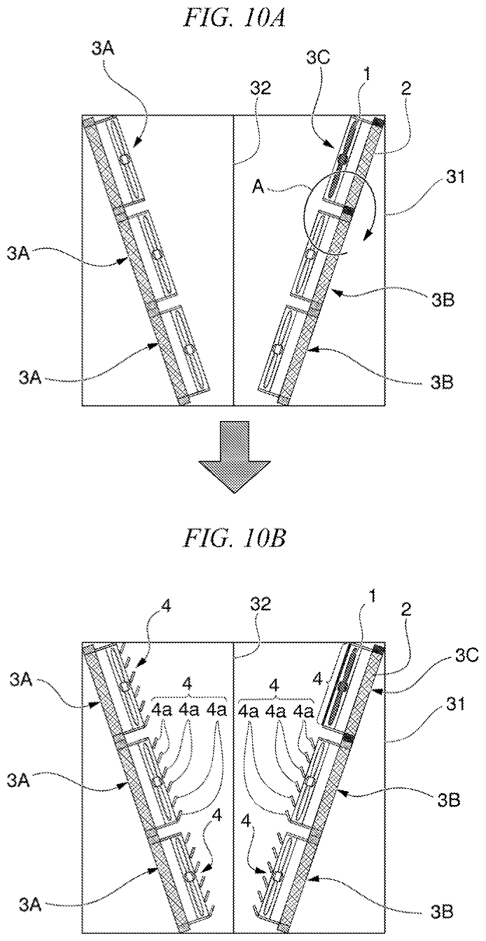

Next, the second exemplary embodiment of the present invention will be described in detail with reference to FIGS. 10A-10B, FIG. 11, and FIGS. 12A-12B. FIG. 10A shows two sets of three heat-radiation modules 3 similar to FIG. 9A, wherein irrespective of a suspension mode of the redundant heat-radiation module 3C at the upper-right position which stops operating the fan 1, the existence of an airflow in an axial direction of the fan 1 of the heat-radiation module 3C may induce a short-return channel of outside air (see an circled arrow A) caused by the operating fan 1 of its adjacent heat-radiation module 3B, which may degrade the radiation capacity of the heat-radiation module 3B. To cope with the above phenomenon, the second exemplary embodiment provides shutters 4 attached to the front faces of the heat-radiation modules 3A, 3B, 3C as shown in FIG. 10B. The shutter 4 includes a plurality of open/close sheets 4a (which can be rotatably moved around axes) aligned on the front face of the fan 1 of the heat-radiation module 3. The shutter 4 is configured to change over a circulation-permit mode to permit circulation of outside air by opening the sheets 4a (see an open state of sheets 4a attached to the heat-radiation modules 3A, 3B) and a circulation-block mode to block circulation of outside air by closing the sheets 4a (see a closed state of sheets 4a attached to the heat-radiation module 3C).

FIG. 11 shows a fixing structure of the shutter 4 whose sheet 4a is fixed using a hinge 60 including a pair of support plates 61 which are interconnected together and rotatably movable about a shaft 62. Specifically, one support plate 61 (e.g., a right-side support plate in FIG. 11) fixedly holds the open/close sheet 4a while the other support plate 61 (e.g., a left-side support plate in FIG. 11) is fixed onto the front face of the fan 1 for each heat-radiation module 3. That is, the support plate 61 fixedly holding the open/close sheet 4a is rotatable movable about the shaft 62 while the other support plate 61 is fixed onto the front face of the fan 1. In other words, the open/close sheet 4a is supported to rotate about the shaft 62.

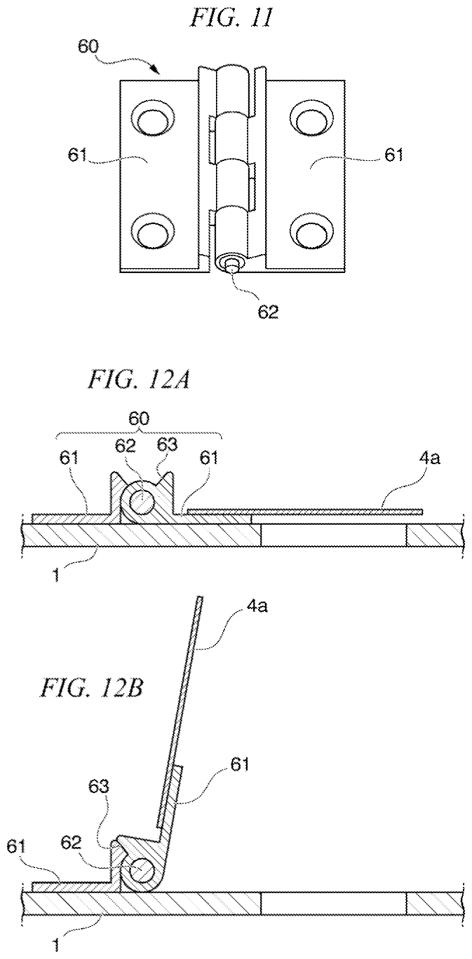

FIG. 12A shows a closed state of the shutter 4 whose sheet 4a stays on the front face of the fan 1 while FIG. 12B shows an open state of the shutter 4 whose sheet 4a is rotated upwardly above the front face of the fan 1. A torsion spring (not shown) is interposed between the support plates 61 to apply torque such that the support plates 61 may rotate in a clockwise direction, and therefore the open/close sheet 4a is normally pressed in a closed state as shown in FIG. 12A. The pressing force of the torsion spring is set to an extent that the open/close sheet 4a may rotate in a counterclockwise direction to open the front face of the fan due to wind pressure caused by the rotating fan 1. In this connection, it is possible to omit the torsion spring depending on a balance among wind pressure of the fan 1, frictional resistance of the hinge 60, and weight of the open/close sheet 4a. In addition, a stopper 63 (see FIGS. 12A-12B) is formed in one support plate 61 to cross a rotation track of the other support plate 61, thus regulating the rotary movement of one support plate 61 between the close state of FIG. 12A and the open state of FIG. 12B.

According to the second exemplary embodiment, in a suspend mode of the redundant heat-radiation module 3C, the open/close sheet 4a closes the front face of the fan 1 as shown in FIG. 12A, and therefore it is possible to prevent a short-return channel of outside air caused by the rotating fan 1 of the adjacent heat-radiation module 3B. By rotating the fan 1 of the redundant heat-radiation module 3C, it is possible to rotate the open/close sheet 4a to open the front face of the fan 1 due to air pressure caused by the fan 1 as shown in FIG. 12B, thus allowing for circulation of outside air via the heat-radiation module 3C.

### Third Exemplary Embodiment

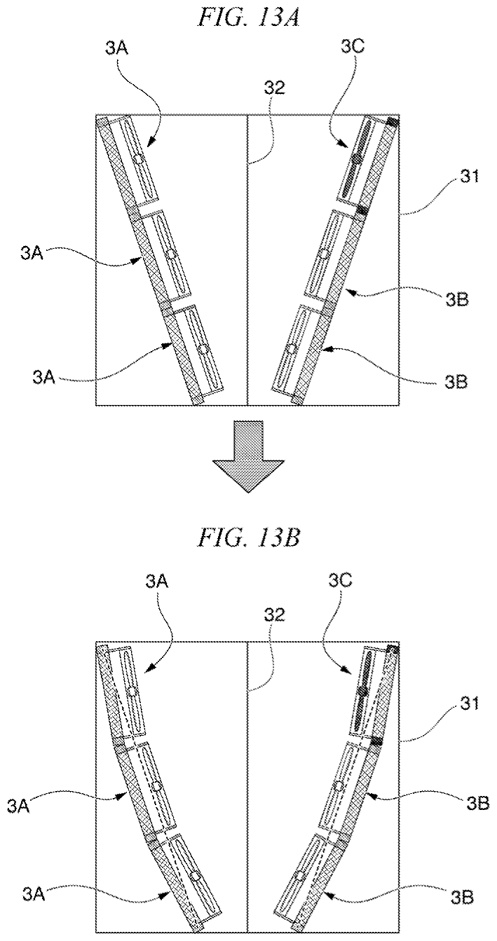

Next, the third exemplary embodiment of the present invention will be described with reference to FIGS. 13A-13B. FIG. 13A shows two sets of three heat-radiation modules similar to those shown in FIG. 9A of the second exemplary embodiment, wherein the left-side vertically-slanted alignment of three heat-radiation modules 3A is positioned opposite to the right-side vertically-slanted alignment of two heat-radiation modules 3B and one redundant heat-radiation module 3C (which is lodged in a suspension mode) via the partition board 32 in the housing 31. In other words, three heat-radiation modules 3A are aligned straightly in a right-downward direction while two heat-radiation modules 3B and one redundant heat-radiation module 3C are aligned straightly in a right-upward direction.

The third exemplary embodiment is characterized by FIG. 13B for aligning two sets of heat-radiation modules opposite to each other via the partition board 32 in the housing 31. Specifically, a left-side set of three heat-radiation modules 3A is aligned downwardly along a negative slope (see a left-side dotted line) while a right-side set of two heat-radiation modules 3B and one redundant heat-radiation module 3C is aligned upwardly along a positive slope (see a right-side dotted line). Specifically, three heat-radiation modules 3A are aligned in a polylinear manner along the left-side dotted line while changing their inclined angles (compared to a vertical line), which are gradually decreased from the lowest position to the top position. In contrast, two heat-radiation modules 3A and one heat-radiation module 3C are aligned in a polylinear manner along the right-side dotted line while changing their inclined angles (compared to a vertical line), which are gradually decreased from the lowest position to the top position.

In FIG. 13B, two sets of three heat-radiation modules 3 are oppositely disposed via the partition board 32 with different distances therebetween in a horizontal direction, wherein those differences are gradually increased from the lowest position to the top position. For example, a distance between the left-side heat-radiation module 3A and the right-side heat-radiation module 3C at the top position is larger than a distance between the left-side heat-radiation module 3A and the right-side heat-radiation module 3B at the lowest position. In addition, an airflow caused by the fan 1 of the left-side heat-radiation module 3A is directed differently than an airflow caused by the fan 1 of the right-side heat-radiation module 3B (or 3C). That is, a difference of directivity between an airflow of the left-side heat-radiation module 3A and an airflow of the right-side heat-radiation module 3B (or 3C) is increased to be larger as a distance between the left-side heat-radiation module 3A and the right-side heat-radiation module 3B (or 3C) becomes smaller. This makes it possible to reduce an increase of loads of DC motors to drive the fans 1 of the oppositely-disposed heat-radiation modules 3 due to an interference between horizontal components of airflows caused by the fans 1 of the oppositely-disposed heat-radiation modules 3. Due to a larger distance between the heat-radiation module 3A and the heat-radiation module 3C (or 3B) at a higher position, an increase of loads of DC motors to drive the fans 1 becomes smaller due to an interference between horizontal components of airflows caused by the fans 1; hence, an inclination of each heat-radiation module 3 compared to a vertical line becomes smaller (or close a vertical line) at a higher position such that an airflow directivity of the fan 1 of the left-side heat-radiation module 3A becomes close to an airflow directivity of the fan 1 of the right-side heat-radiation module 3C (or 3B) at a higher position.

In this connection, FIG. 13B shows two sets of three heat-radiation modules 3 aligned along negative and positive slopes in a polylinear manner, however, it is possible to arrange more sets of three heat-radiation modules 3 in a backward direction of FIG. 13B. In addition, FIG. 13 shows that all the three heat-radiation modules 3 are aligned along a slope in a polylinear manner with different inclination angles compared to a vertical line. However, it is possible to align three heat-radiation modules 3 along a slope such that some of the three heat-radiation modules 3 may be aligned with a different inclination angle compared to a vertical line.

Heretofore, although the non-limiting exemplary embodiments of the present invention are described in detail with reference to the accompanying drawings, the detailed structures of the heat-radiation apparatuses are not necessarily limited to the foregoing embodiments; hence, the present invention may embrace any modifications or design changes without departing from essential features of the invention as defined in the appended claims.

For example, the accompanying drawings show two sets of heat-radiation modules which are oppositely aligned via the partition board and oppositely inclined to each other; however, this is not a restriction. It is possible to provide three or more sets of heat-radiation modules which are separately positioned via the partition board(s) and inclined with different angles or with the same angle in the housing.

Lastly, the present invention is advantageous in reducing electric power for driving small-size fans attached to heat exchangers, in particular, the present invention is applicable to exterior units of air conditioners utilizing DC power rather than AC power.

While non-limiting embodiments of the invention have been described and illustrated above, it should be understood that these are exemplary of the invention and are not to be considered as limiting. Additions, omissions, substitutions, and other modifications can be made without departing from the scope of the present invention. Accordingly, the invention is not to be considered as being limited by the foregoing descriptions, and is only limited by the scope of the appended claims.

What is claimed is:

1. A heat-radiation apparatus comprising:
a housing: and
a plurality of heat-radiation modules which are aligned in a vertically-slanted manner with a predetermined inclination angle to a vertical line in the housing,
wherein the plurality of heat-radiation modules includes a plurality of heat exchangers and a plurality of fans, and
wherein the plurality of heat exchangers is aligned together in parallel and equipped with the plurality of fans to parallelize axial lines thereof with each other.

2. The heat-radiation apparatus according to claim 1, further comprising a partition board disposed along the vertical line in the housing, wherein the partition board is interposed between the plurality of fans.

3. The heat-radiation apparatus according to claim 1, further comprising a frame body to detachably and individually keep the plurality of heat-radiation modules.

4. The heat-radiation apparatus according to claim 1, wherein the plurality of fans is each equipped with a plurality of shutters configured to open or close a front face of each fan according to wind power produced by each fan.

5. The heat-radiation apparatus according to claim 1, wherein the plurality of fans is driven by a DC power supply to individually operate or stop each fan among the plurality of fans.

6. The heat-radiation apparatus according to claim 1, wherein at least one heat-radiation module among the plurality of heat-radiation modules serves as a redundant heat-radiation module normally in a suspension mode to stop its fan.

7. A heat-radiation apparatus comprising:
a housing;
a partition board arranged inside the housing along its vertical line;
a plurality of heat-radiation modules including a plurality of heat exchangers and a plurality of fans, wherein the plurality of heat exchangers is aligned together in parallel and equipped with a plurality of fans to parallelize axial lines thereof with each other,
wherein the plurality of heat-radiation modules includes at least a first set of heat-radiation modules and a second set of heat-radiation modules, which are separately positioned via the partition board in the housing and inclined to the vertical line in the housing.

8. The heat-radiation apparatus according to claim 7, wherein the first set of heat-radiation modules is aligned along a first polyline as the first slope to differentiate the first inclination angle at different heights along the vertical line while the second set of heat-radiation modules is aligned along a second polyline as the second slope to differentiate the second inclination angle at different heights along the vertical line.

9. A manufacturing method of a heat-radiation apparatus comprising a plurality of heat-radiation modules, the manufacturing method comprising:
aligning the plurality of heat-radiation modules including a plurality of heat exchangers in a vertically-slanted manner with a predetermined inclination angle to a vertical line in a housing such that the plurality of heat exchangers is aligned together in parallel and equipped with a plurality of fans to parallelize axial lines thereof with each other; and
adjusting the number of heat-radiation modules as the plurality of heat-radiation modules according to a radiation amount which is determined in advance.
